(19) United States
(12) Patent Application Publication
(10) Pub. No.: US 2022/0090283 A1
(43) Pub. Date: Mar. 24, 2022

(54) ELECTRODEPOSITION OF A COBALT OR COPPER ALLOY, AND USE IN MICROELECTRONICS

(71) Applicant: aveni, Massy (FR)

(72) Inventors: Vincent MEVELLEC, Boulogne (FR); Louis CAILLARD, Cachan (FR); Mikaïlou THIAM, Compiegne (FR); Dominique SUHR, Chatenay - Malabry (FR)

(21) Appl. No.: 17/429,470

(22) PCT Filed: Feb. 6, 2020
(86) PCT No.: PCT/EP2020/053018

§ 371 Date: Aug. 9, 2021

(30) Foreign Application Priority Data
Feb. 8, 2019 (FR) 1901264
Jan. 14, 2020 (FR) 2000297

(51) Int. Cl. C25D 3/56; C25D 3/58; C25D 5/50; C25D 7/12

(52) U.S. Cl. CPC C25D 3/562; C25D 7/123; C25D 5/50; C25D 3/58

(57) ABSTRACT

Electrodeposition of a cobalt or copper alloy, and use in microelectronics The present invention relates to a process for fabricating cobalt or copper interconnects, and to an electrolyte enabling implementation of said process. The electrolyte, with a pH of less than 4.0, comprises cobalt or copper ions, chloride ions, manganese or zinc ions, and at most two organic additives of low molecular mass. One of these additives may be an alpha-hydroxy carboxylic acid.

### TECHNICAL FIELD

The present invention concerns an electrolyte and the use thereof for electrodeposition of an alloy of a first metal selected from cobalt, copper and mixtures thereof and a second metal selected from manganese, zinc and mixtures thereof on a conductive surface. The invention likewise concerns a fabrication process which employs this electrolyte and may be used to produce electrical cobalt or copper interconnects in integrated circuits. The invention lastly concerns a device comprising a layer of the first metal in contact with a layer of the second metal.

### PRIOR ART

The conventional processes for filling interconnects with cobalt employ electrolytes containing a cobalt salt and numerous organic additives, including a suppressor and an accelerator with complementary functions, for obtaining what is called bottom-up filling. For obtaining a good-quality cobalt mass, more particularly with no material voids, it is generally necessary for these additives to be combined. The suppressor controls the deposition of the cobalt at the opening of the cavities and on the flat surface of the substrate which surrounds the cavities, by adsorbing onto the cobalt surface or by complexing with the cobalt ions. This compound may therefore be a molecule of high molecular mass such as a polymer which is unable to diffuse inside the cavities, or an agent which complexes cobalt ions. The accelerator, for its part, diffuses to the bottom of the cavities, and its presence is all the more necessary in cavities of great depth. It allows an increase in the rate of deposition of the cobalt at the bottom of the cavities and also on their walls. The method of filling via a bottom-up mechanism contrasts with a method of filling termed “conformal” or “continuous”, in which the cobalt deposit grows at the same rate at the bottom and on the walls of the hollow patterns.

These electrodeposition baths and their use have a number of drawbacks which ultimately limit the good operation of the electronic devices fabricated and which make them too expensive to fabricate. The reason is that they give rise to cobalt interconnects which are contaminated with the organic additives required in order to limit the formation of fill holes in the cobalt. Moreover, the filling rates obtained which these chemistries are too slow and are not compatible with industrial-scale production.

Patent application US 2015/0179579 described the use of manganese for enhancing the adhesion of cobalt in interconnects, more specifically on mixed cobalt/dielectric substrates for the purpose of fabricating the grating of a MOSFET transistor. In the process described, however, the manganese and the cobalt are deposited during two successive, independent steps of material deposition: a step of chemical deposition of the manganese in vapour phase, followed by a step of electrodeposition of the cobalt.

There is therefore still a need to provide electrolysis baths which lead to cobalt deposits featuring enhanced performance, i.e. which have extremely reduced impurities contents, the formation rate of which is sufficiently high to make it profitable to fabricate electronic devices and/or to allow a reduction in thickness, or even to obviate the deposition, of a layer of a cobalt diffusion barrier material, such as tantalum nitride, between the insulating substrate based on silicon dioxide, for example, and cobalt.

The inventors have found that a solution with a pH of between 1.8 and 4.0, containing cobalt II ions and metal ions selected from manganese II ions and zinc II ions, allows this objective to be attained.

The possibility of depositing a cobalt alloy at a pH of less than 4, using in particular an alpha-hydroxy carboxylic acid in a conformal electrodeposition process, has never been suggested, so making the results of the invention all the more surprising. Over and above this, the possibility of forming a thin layer based on manganese or on zinc without entailing a chemical or physical deposition step prior to the deposition of the cobalt had never yet been proposed.

The inventors have found that the same result is achieved with copper II ions, in substitution for the cobalt II ions, so that the invention enables the production of copper deposits featuring enhanced performance, i.e. which have extremely reduced impurities contents, the formation rate of which is sufficiently high to make it profitable to fabricate electronic devices and/or to allow a reduction in thickness, or even to obviate the deposition, of a layer of a cobalt diffusion barrier material, such as tantalum nitride, between the insulating substrate based on silicon dioxide, for example, and copper.

### GENERAL DESCRIPTION OF THE INVENTION

Accordingly the invention concerns an electrolyte for electrodeposition of an alloy of a first metal selected from cobalt, copper and mixtures thereof, and a second metal selected from manganese, zinc and mixtures thereof, characterized in that the electrolyte is an aqueous solution comprising:
cobalt II ions or copper II ions in a mass concentration of from 1 g/L to 5 g/L,
chloride ions in a mass concentration of from 1 g/L to 10 g/L,
metal ions selected from manganese II ions and zinc II ions, said metal ions being in a mass concentration such that the ratio between the mass concentration of cobalt II ions or of copper II ions and the mass concentration of metal ions is from 1/10 to 25/1,
an organic acid or an inorganic acid in an amount sufficient to obtain a pH for the electrolyte being between 1.8 and 4.0, and
just one or at most two organic additives which are not polymers, wherein said organic additive, one of the two organic additives or the two organic additives may be the organic acid if present in the composition, and wherein the concentration of the organic additive or the sum of the concentrations of the two organic additives is between 5 mg/L and 200 mg/L.

The ratio between the mass concentration of cobalt II ions (or copper II ions) and the mass concentration of metal ions may be higher than a value selected in the group consisting of 1/10, 1/5, 1/3, 1/2, 1/1, 2/1, 3/1, 5/1, 10/1, 15/1 and 20/1. The ratio between the mass concentration of cobalt II ions (or copper II ions) and the mass concentration of metal ions may be lower than a value selected in the group consisting of 1/5, 1/3, 1/2, 1/1, 2/1, 3/1, 5/1, 10/1, 15/1, 20/1 and 25/1.

The invention likewise concerns a process for filling cavities with cobalt or copper, comprising a first step of conformally depositing an alloy, which uses the electrolyte above, and a second step of annealing the alloy to give a cobalt or copper deposit.

The electrolyte and the process of the invention provide access to continuous deposits of cobalt or of copper which are of high purity, and within a fabrication time which is compatible with industrial applications.

An advantage of the cobalt or copper deposits is that they are of very high purity, essentially for three reasons.

One of the objectives pursued in the prior art is to slow down metal deposition at the entry of the cavities, using suppressors which adsorb specifically on the flat surface of the substrate (surface suppressors), without penetrating the hollows that the conductive metal is to fill.

These organic additives, which are used in large quantity in the prior art and are needed to ensure quality filling, give rise to contamination of the cobalt or copper deposit. The process of electrodeposition employed by virtue of the electrolyte of the invention, though, follows a cavity filling method which is conformal and does not require the use of these additives.

The electrolyte and the process of the invention therefore enable considerable limitation on the contamination of the cobalt or copper deposit, by limiting the concentration of organic molecules, the presence of a buffer substance at a high concentration, and the formation of cobalt hydroxide or copper hydroxide during the electrodeposition.

Furthermore, the electrolyte and the process of the invention provide access to cobalt or copper interconnects having a very low impurities rate, of preferably less than 1000 ppm atomic, while being formed at a greater deposition rate.

The electrolyte and the process of the invention, lastly, make it possible to form a thin layer comprising manganese or zinc, by annealing an alloy of cobalt and manganese, an alloy of cobalt and zinc, an alloy of copper and manganese or an alloy of copper and zinc, this alloy being deposited in a single step by electrodeposition.

In one particular embodiment, a cobalt-manganese or copper-manganese alloy is deposited on the surface of a seed layer made of a metallic material, this layer covering an insulating material. A heat treatment is then carried out on the alloy, allowing separation of the cobalt and the manganese or of the copper and the manganese, and producing a layer containing cobalt or copper, on the one hand, and a layer of manganese, on the other. During the annealing of the alloy, the manganese atoms distributed within the alloy migrate to the interface between the metal layer and the insulating material, to form a thin layer of manganese interposed between the metal layer and the insulating material. The result is a stack of an insulating substrate covered with a thin layer of manganese, a thin metal layer, and a deposit of cobalt or copper. The annealing enhances the profitability of fabrication and the reliability of electronic devices comprising cobalt or copper interconnects.

Lastly, the process of the invention, in the case of cobalt, allows a reduction in thickness or even the non-deposition of a layer of a cobalt diffusion barrier material, such as tantalum nitride, between the insulating substrate, based on silicon dioxide, and the cobalt. The same result is obtained in the case of copper.

### DEFINITIONS

“Electrolyte” refers to the liquid which contains precursors of a metal coating used in an electrodeposition process.

“Continuous filling” refers to a cobalt mass or a copper mass which is free from voids. In the prior art, holes or voids of material can be observed in a cobalt or copper deposit between the walls of the patterns and the metal deposit (“sidewall voids”). There are also voids observable which are situated at equal distance from the walls of the patterns, in the form of holes or lines (“seams”). These voids may be observed and quantified by transmission or scanning electron microscopy, by making cross sections of the deposits. The continuous deposit of the invention preferably has an average void percentage of less than 10% by volume, preferably less than or equal to 5% by volume. Measurement of the void percentage within the structures to be filled may be accomplished by electron microscopy at a magnification of between 50 000 and 350 000, or by TEM.

“Average diameter” or “average width” of the cavities refers to dimensions measured at the opening of the cavities to be filled. The cavities are for example in the form of tapered channels or cylinders. “Conformal filling” refers to a filling mode in which a deposit of an alloy of cobalt and manganese, an alloy of cobalt and zinc, an alloy of copper and manganese or an alloy of copper and zinc grows at the same rate at the bottom and on the walls of the hollow patterns. This filling mode contrasts with a filling from the bottom to the top (“bottom-up” filling), in which the rate of deposition of the alloy is higher at the bottom of the cavities.

### DETAILED DESCRIPTION OF THE INVENTION

The invention concerns an electrolyte for electrodeposition of an alloy of a first metal, selected from cobalt, copper and mixtures thereof, and a second metal, selected from manganese, zinc and mixtures thereof, said alloy comprising a metal selected from manganese and zinc, characterized in that the electrolyte is an aqueous solution comprising
cobalt II or copper II ions in a mass concentration of from 1 g/L to 5 g/L,
chloride ions in a mass concentration of from 1 g/L to 10 g/L,
metal ions selected from manganese II ions and zinc II ions, said metal ions being in a mass concentration such that the ratio between the mass concentration of cobalt II ions or of copper II ions and the mass concentration of metal ions is from 1/10 to 10/1,
an organic or inorganic acid in an amount sufficient to obtain a pH of between 1.8 and 4.0, and
just one or at most two organic additives which are not polymers, where one of the two additives may be the acid; when this acid is an organic acid, the concentration of the additive or the sum of the concentrations of the two additives is between 5 mg/L and 200 mg/L.

The organic additives are preferably not sulfur-containing additives, with at least one of them, or even both, being preferably an alpha-hydroxy carboxylic acid. The electrolyte preferably comprises a single organic additive.

The organic additive or additives preferably have a molecular mass of less than 250 g/mol, preferably less than 200 g/mol, and greater than 50 g/mol, more preferably greater than 100 g/mol.

The concentration of the additive or the sum of the concentrations of the two additives is preferably between 5 mg/L and 200 mg/L. In this embodiment, the additives may each be an alpha-hydroxy carboxylic acid not containing sulfur.

At least one of the organic additives may be selected from citric acid, tartaric acid, malic acid, mandelic acid, maleic acid, fumaric acid, glyceric acid, orotic acid, malonic acid, L-alanine, acetylsalicylic acid and salicylic acid.

The mass concentration of cobalt II or copper II ions may be from 1 g/L to 5 g/L, for example from 2 g/L to 3 g/L. That of the chloride ions may be from 1 g/L to 10 g/L.

A relatively high concentration of cobalt or copper ions at a highly acidic pH has a number of advantages in relation to the electrolytic baths of the prior art, which have a basic or slightly acidic pH and a lower cobalt or copper ion concentration.

The reason is that the inventors found that it is not necessary to operate at a pH of more than 4 in order to limit the corrosion of the cobalt or the copper in the deposit. By increasing the concentration of cobalt ions or of copper ions, and by lowering the value of the pH, it appears to be possible to stabilize the metallic cobalt or copper by substantially increasing the concentration of the ions present in the aqueous solution. The inventors have thus observed a deposition rate which is greater than that of the prior art, and also a high size of the grains of the cobalt or copper in the deposit after the annealing step, typically greater than 20 nm.

The metal ions are selected from manganese II ions and zinc II ions. Their mass concentration is such that the ratio between the mass concentration of cobalt ions or of copper ions and the mass concentration of metal ions is from 1/10 to 25/1 or from 1/10 to 10/1.

The chloride ions may be provided by dissolving in water i) cobalt chloride or copper chloride, or one of their hydrates, such as cobalt chloride hexahydrate, and ii) manganese chloride or zinc chloride.

The composition is preferably not obtained by dissolving a salt comprising sulfate, which gives rise to sulfur contamination of the cobalt or copper deposit, an undesirable phenomenon.

The organic additive or additives are preferably not sulfur-containing, and are preferably selected from alpha-hydroxy carboxylic acids such as the compounds citric acid, tartaric acid, glycolic acid, lactic acid, malic acid, mandelic acid, maleic acid, oxalic acid and 2-hydroxybutyric acid.

The electrolyte may comprise an organic additive other than an alpha-hydroxy carboxylic acid, such as glycine or ethylenediamine. It may be of any kind, provided that it does not give rise to a bottom-up filling effect. The electrolyte of the invention, indeed, is preferably devoid of surface suppressor polymers such as polyethylene glycols, polypropylene glycols, polyvinylpyrrolidones or polyethyleneimines.

The cobalt II or copper II ions and the metal ions (manganese II or zinc II) are advantageously in free form, meaning that they are not complexed with the organic additive or additives, more particularly when the pH is less than 3, whether in the absence of polarization or during the polarization of the conductive surface.

There are numerous advantages to not having a substantial quantity of cobalt or copper complexes or of other metal complexes with an organic molecule: it enables a reduction in the organic contamination of the metal deposit, because the concentration of organic molecules in the bath may be very low; it likewise enables the avoidance—during the period of time in which the cobalt or copper is deposited in the structures—of any uncontrolled variation in the pH liable to destabilize the solution. Moreover, the cobalt or copper ions are not stabilized by the complex, and can be reduced more easily, and so the rate of deposition of the cobalt or the copper is greater. Lastly, the very high concentration of cobalt or copper ions protects the conductive surface of the cavities from corrosion. This effect is determining when the substrate is covered with a layer of very low thickness (seed layer), which serves as a conductive surface during electrodeposition.

The electrolyte of the present invention advantageously comprises one of the following features, taken alone or in combination:
It does not comprise an accelerator of cobalt or copper growth at the bottom of the patterns,
The electrolyte does not contain an organic suppressor molecule capable of slowing down the growth of the cobalt or copper on the flat part of the substrate at the opening of the cavities, by specifically adsorbing on the cobalt or on the copper, which is deposited at this site during electrodeposition,
It does not comprise a combination of additives giving rise to a bottom-up filling mechanism, particularly the combination of a suppressor and an accelerator, or the combination of a suppressor, an accelerator and a leveller,
It does not comprise a polymer—with polymer meaning a molecule having at least four repeating units,
It does not comprise a sulfur-containing compound.

Surface suppressors include the following compounds: carboxymethylcellulose, nonylphenol polyglycol ether, polyethylene glycol dimethyl ether, octanediolbis(polyalkylene glycol ether), octanol polyalkylene glycol ether, polyglycol ester of oleic acid, polyethylene glycol-propylene glycol, polyethylene glycol, polyethyleneimine, polyethylene glycol dimethyl ether, polyoxypropylene glycol, polypropylene glycol, polyvinyl alcohol, polyglycol ester of stearic acid, polyglycol ether of stearyl alcohol, butyl alcohol-ethylene oxide-propylene oxide copolymers, 2-mercapto-5-benzimidazolesulfonic acid, 2-mercaptobenzimidazole.

An accelerator is generally a compound comprising a sulfur atom, for example the 3-sulfopropyl ester of N,N-dimethyldithiocarbamic acid, the 3-sulfopropyl ester of 3-mercaptopropylsulfonic acid, 3-sulfanyl-1-propane sulfonate, the ester of dithiocarbonic acid o-ethyl ester s-ester with the potassium salt of 3-mercapto-1-propanesulfonic acid, bissulfopropyl disulfide, a sodium salt of 3-(benzothiazolyl-s-thio)propylsulfonic acid, pyridinium propylsulfobetaine, 1-sodium 3-mercaptopropane-1-sulfonate, the 3-sulfoethyl ester of N,N-dimethyldithiocarbamic acid, the 3-sulfoethyl ester of 3-mercapto-ethylpropylsulfonic acid, a sodium salt of 3-mercaptoethylsulfonic acid, pyridinium ethylsulfobetaine or thiourea.

In the first embodiment, the pH of the electrolyte is preferably between 1.8 and 4.0. In one particular embodiment, the pH is between 2.0 and 3.5, or between 2.0 and 2.4.

The pH of the composition may optionally be adjusted with a base or an acid known to those skilled in the art. The acid may be organic or inorganic. Preference is given to using a strong inorganic acid such as hydrochloric acid.

Although there is no restriction in principle on the nature of the solvent (provided that it sufficiently dissolves the active species of the solution and does not interfere with the electrodeposition), it will preferably be water. According to one embodiment, the solvent comprises predominantly water by volume.

According to one variant, an electrolyte of the invention has a pH of between 1.8 and 4.0, for example between 2.0 and 4.0, and comprises in aqueous solution cobalt II or copper II ions, metal ions of manganese II or zinc II, chloride ions, and between 5 and 200 mg/L of one or more compounds having a pKa of from 1.8 to 3.5, preferably from 2.0 to 3.5, and more preferably from 2.2 to 3.0.

The compound preferably has a molecular mass of less than 250 g/mol, preferably less than 200 g/mol, and more than 50 g/mol, preferably more than 100 g/mol.

In certain cases, the compound having a pKa value of from 1.8 to 3.5 may be identical to at least one of the organic additives used in the first embodiment. It may more particularly be selected from citric acid, tartaric acid, malic acid, maleic acid and mandelic acid.

It may also be selected from the compounds fumaric acid (pKa=3.03), glyceric acid (pKa=3.52), orotic acid (pKa=2.83), malonic acid (pKa=2.85), L-alanine (pKa=2.34), phosphoric acid (pKa=2.15), acetylsalicylic acid (pKa=3.5) and salicylic acid (pKa=2.98).

The prior-art processes of cobalt filling employ alkaline electrolytes, with a pH of more than 4, for example, while applying very low current densities and suppressor compounds that are specific to cobalt, and so the pH inside the trenches remains greater than 4 throughout the filling step, so giving rise to substantial formation of cobalt hydroxide in the resulting cobalt deposit, with said cobalt hydroxide reducing the conductivity of the cobalt interconnects and decreasing the performance levels of the integrated circuits.

The electrolyte of the invention and the process of the invention aim specifically to solve this problem, by considerably limiting the formation of cobalt hydroxide so that it is present only in trace amounts in the cobalt that has been deposited. The solution to this problem involves using an electrolyte with a pH of between 1.8 and 4.0, for example between 2.0 and 4.0, to which an additive is added which exhibits preferably at least one, or even all, of the features such as:
a local buffering capacity within the trenches, on their surface, which allows the pH of the electrolyte to be maintained throughout the substrate polarization time at a value of greater than 1.8 or 2.0 and less than 3.5, and preferably less than 2.5,
a low molecular mass, so that the additive is able to diffuse into the structures with a low average diameter at the opening or with a low average width, and
a very low concentration in the electrolyte, such that the amount of additive present in the electrolyte before the start of polarization diffuses almost totally into the cavities of the structures, and such that the additive has a local buffering capacity.

An electrolyte comprising an additive of this kind enables selective limitation—for example, solely in the cavities of the structures and not at the flat surface of the substrate—on an increase in the pH to a value of less than 4.0, preferably less than 3.0 and more preferably to a value of between 2.0 and 2.5. The additive is therefore able advantageously to fulfil the function of a buffering agent, by exerting its effect locally, i.e. solely in the cavities. The organic additive or the compound having a pKa of from 1.8 to 3.5 or from 2.0 to 3.5 is able to act as a local buffering agent, the effect of which is observed only in the cavities.

According to a first embodiment, the first metal is cobalt and the second metal is manganese. According to a second embodiment, the first metal is cobalt and the second metal is zinc. According to a third embodiment, the first metal is copper and the second metal is manganese. According to a fourth embodiment, the first metal is copper and the second metal is zinc.

For example, the electrolyte is an aqueous solution comprising:
cobalt II ions in a mass concentration of from 1 g/L to 5 g/L,
chloride ions in a mass concentration of from 1 g/L to 5 g/L,
zinc II ions being in a mass concentration such that the ratio between the mass concentration of cobalt II ions and the mass concentration of zinc II ions is from 15/1 to 20/1,
an inorganic acid in an amount sufficient to obtain a pH of between 2.0 and 2.4, and
just one organic additive, the concentration of which is between 10 mg/L and 20 mg/L.

In this example, the organic additive may be tartaric acid.

The invention likewise concerns an electrochemical process for filling cavities, said cavities having an average width or an average diameter at the opening of between 15 nm and 100 nm and a depth of between 50 nm and 250 nm, said process comprising:
a step of contacting a conductive surface of said cavities with an electrolyte in accordance with the description above,
a step of polarizing the conductive surface for a period of time sufficient to carry out the conformal and complete filling of the cavities by deposition of an alloy of a first metal selected from cobalt, copper and mixtures thereof and a second metal selected from manganese, zinc and mixtures thereof, and
a step of annealing the deposit of the alloy obtained at the end of the polarization step, said annealing being carried out at a temperature which allows the metal to migrate to form a first layer containing predominantly the metal, said layer having a thickness of between 0.5 and 2 nm, and a second layer containing essentially cobalt or copper.

The annealing step also enables an improvement in the crystallinity of the cobalt or the copper, and the suppression of any material voids in the deposit.

In one particular embodiment, the conductive surface is the first surface of a metallic seed layer having a thickness of from 1 to 10 nanometres, said seed layer having a second surface in contact with a dielectric material comprising silicon dioxide. The metallic seed layer may comprise a metal selected from the group consisting of cobalt, copper, tungsten, titanium, tantalum, ruthenium, nickel, titanium nitride and tantalum nitride.

In one particular embodiment, the seed layer is a cobalt seed layer. The process of the invention may be implemented with one of the above-described electrolytes comprising one or two non-polymeric organic additives, or comprising between 5 mg/L and 200 mg/L of one or more compounds having a pKa of from 1.8 to 3.5, preferably from 2.0 to 3.5, and more preferably from 2.2 to 3.0.

Throughout the time during which the filling step of the process of the invention is implemented, the pH inside the cavities advantageously remains less than 3.5, or even less than 3.0, depending on the type of electrolyte used.

The cavities may be designed in the context of the implementation of a damascene or dual damascene process. The cavities may especially be obtained by implementation of the following steps:
a step of etching structures into a silicon substrate,
a step of forming a layer of silicon oxide on a silicon surface of the structures, to give a silicon oxide surface,
a step of depositing a layer of metal on said layer of silicon oxide, so as to give the cavities a conductive surface.

The metal layer is preferably a metallic seed layer having a thickness of between 1 nm and 10 nm. It is preferably deposited on a layer of silicon oxide, which is in contact with the silicon. The metal may comprise at least one compound selected from the group consisting of cobalt, copper, tungsten, titanium, tantalum, ruthenium, nickel, titanium nitride and tantalum nitride. The metal layer preferably comprises a cobalt layer. In a first embodiment, the metal layer is composed of a cobalt layer. In a second embodiment, the metal layer comprises a cobalt layer and a layer of a material possessing a cobalt diffusion barrier property. The metal layer may be deposited by any appropriate method known to those skilled in the art.

The process of the invention is a “conformal” process, as opposed to the “bottom-up” or “super-conformal” processes of the prior art. In the conformal filling process of the invention, the cobalt alloy or copper alloy deposit grows at the same rate at the bottom and on the walls of the hollow patterns to be filled. This filling mode contrasts with the other processes of the prior art, in which the rate of deposition of the cobalt alloy is higher at the bottom of the cavities than on the walls of the cavities.

The manganese content or the zinc content of the alloy deposited at the end of the electrodeposition step is preferably between 0.5 atomic % and 10 atomic %, for example between 1.0 atomic % and 5.0 atomic %, or between 1.5 atomic % and 2.5 atomic %

The intensity of the polarization used in the electrical step is preferably from 2 mA/cm² to 50 mA/cm², whereas it is generally from 0.2 mA/cm² to 1 mA/cm² in the prior-art processes where an alkaline electrolyte is used.

The electrical step of the process of the invention may comprise just one or several polarization steps, in which those skilled in the art will know how to select the variables on the basis of their general knowledge.

The electrical step may be carried out using at least one polarization mode selected from the group consisting of ramp mode, galvano-static mode and galvano-pulsed mode.

The electrical step may therefore comprise at least one step of electrodeposition in galvano-pulsed mode and at least one step of electrodeposition in galvano-static mode, the electrodeposition step in galvano-static mode preferably following the electrodeposition step in galvano-pulsed mode.

For example, the electrical step comprises a first step of polarization of the cathode in galvano-pulsed mode, alternating a current of from 3 mA/cm² to 20 mA/cm², for example from 12 mA/cm² to 16 mA/cm², for a time (Tₒₙ) of preferably between 5 and 50 ms, and a zero polarization for a time (T_{off}) of preferably between 50 ms and 150 ms.

In this first step, the substrate may be contacted with the electrolyte either before polarization or after polarization. Contacting with the cavities is preferably performed before the application of voltage, so as to limit the corrosion of the metal layer which comes into contact with the electrolyte.

In a second step, the cathode may be polarized in galvano-static mode, with a current ranging from 3 mA/cm² to 50 mA/cm². The two steps are preferably of substantially the same duration.

The second step in galvano-static mode may itself comprise two steps: a first step, in which the current has an intensity of from 3 mA/cm² to 8 mA/cm², and a second step, in which a current with an intensity of from 9 mA/cm² to 50 mA/cm² is applied.

This electrical step may especially be used when the electrolyte has a pH of between 2.5 and 3.5.

In another example, the electrical step comprises a first step of polarization of the cathode in ramp mode, with a current which goes preferably from 0 mA/cm² to 15 mA/cm², preferably from 0 mA/cm² to 10 mA/cm², followed by a step in galvano-static mode, with application of a current of from 10 mA/cm² to 50 mA/cm², preferably from 8 mA/cm² to 20 mA/cm². This electrical step may especially be used when the electrolyte has a pH of between 2.0 and 2.5.

The electrodeposition step is generally stopped when the alloy deposit covers the flat surface of the substrate: in this case, the deposit comprises the material inside the cavities and the material covering the surface of the substrate in which the cavities have been hollowed out. The thickness of the alloy layer covering the surface may be between 50 nm and 400 nm, and may for example be between 125 nm and 200 nm.

The deposition rate of the cobalt alloy or copper alloy is between 0.1 nm/s and 3.0 nm/s, preferably between 1.0 nm/s and 3.0 nm/s, and more preferably between 1 nm/s and 2.5 nm/s.

The process of the invention comprises a step of annealing the alloy deposit obtained at the end of filling as described above.

This annealing heat treatment may be performed at a temperature of between 50° C. and 550° C., preferably under a reducing gas such as H₂ at 4% in N₂.

A low impurities content in combination with a very low percentage of voids provides access to a cobalt deposit or a copper deposit having a lower resistivity.

During the annealing step, the manganese or zinc atoms present in the alloy migrate towards the surface of the conductive substrate, so resulting in the formation of two layers: a first layer, comprising essentially the cobalt or the copper, and a second layer, comprising essentially the manganese or the zinc. A layer comprising “essentially” cobalt may be a layer comprising at most 100% cobalt and a minimum amount of cobalt selected from the group consisting of 95%, 96%, 97%, 98%, 99%, 99.5%, 99.8% and 99.9%. A layer comprising “essentially” copper may be a layer comprising at most 100% copper and a minimum amount of copper selected from the group consisting of 95%, 96%, 97%, 98%, 99%, 99.5%, 99.8% and 99.9%. A layer comprising “essentially” manganese may be a layer comprising at most 100% of manganese and a minimum amount of manganese selected from the group consisting of 95%, 96%, 97%, 98%, 99%, 99.5%, 99.8% and 99.9%. A layer comprising “essentially” zinc may be a layer comprising at most 100% zinc and a minimum amount of zinc selected from the group consisting of 95%, 96%, 97%, 98%, 99%, 99.5%, 99.8% and 99.9%. These percentages are atomic %, and can be measured by any method known from one skilled in the art.

In one embodiment, the conductive surface is the surface of a cobalt seed layer, said layer covering an insulating substrate comprising silicon dioxide. In this embodiment, the manganese or zinc atoms migrate during the annealing step through the cobalt seed layer to reach the interface between the first seed layer and the insulating substrate comprising silicon dioxide.

The total impurities content of the cobalt deposit or copper deposit obtained by the electrodeposition and annealing process of the invention is less than 1000 ppm atomic, the manganese or zinc not being considered to be impurities. The impurities include primarily oxygen, followed by carbon and nitrogen. The total carbon and nitrogen content is less than 300 ppm. The cobalt or copper deposit is advantageously continuous. It preferably has an average void percentage of less than 10% by volume or by surface area, preferably of less than or equal to 5% by volume or by surface area. The void percentage in the cobalt or copper deposit may be measured by observation by electron microscopy, which is known to those skilled in the art, who will select the method appearing to them to be the most appropriate. One of these methods may be scanning electron microscopy (SEM) or transmission electron microscopy (TEM) using a magnification of between 50 000 and 350 000. The void volume may be evaluated by measuring the void surface area observed on one or more cross sections of the substrate comprising the filled cavities. Where two or more surface areas are measured on two or more cross sections, the average of these surface areas will be calculated in order to evaluate the void volume.

The layer comprising essentially the manganese or the zinc is preferably a continuous layer having an average thickness of from 0.5 nm to 2 nm. By “continuous” is meant that the layer covers the entirety of the surface of the dielectric substrate without the latter showing through. The thickness of the layer varies preferably by +/−10% relative to the average thickness.

The process may comprise a preliminary step of treatment by reductive plasma so as to reduce the native metal oxide present at the surface of the substrate. The plasma also acts on the surface of the trenches, thereby enabling an improvement in the quality of the interface between the conductive surface and the alloy. The subsequent electrodeposition step is preferably carried out immediately after the plasma treatment, in order to minimize the reformation of native oxide.

The process of the invention finds application particularly in the fabrication of semiconductor devices, during the production of the conductive metal interconnects, such as trenches running along the surface or vias connecting different levels of integration.

Lastly, the invention concerns a semiconductor device equipped with metal interconnects comprising a layer of a dielectric material, which is covered by and in contact with a layer comprising essentially manganese or zinc, said layer being covered by a cobalt or copper layer.

A metal seed layer may be inserted between the layer comprising essentially manganese or zinc, and the cobalt or copper layer, and may be in contact with each of these two layers. The interconnects are composed essentially of cobalt or copper and are obtainable by the process described above. In this case they correspond to the cobalt or copper deposit which fills the cavities. The interconnects may have an average width of between 15 nm and 100 nm and an average depth of between 50 nm and 250 nm.

The layer comprising essentially manganese or zinc advantageously has a thickness of between 0.5 nm and 2 nm, and is in contact with the dielectric material, such as silicon dioxide.

The present description also deals with a method of forming a metal interconnect structure comprising one adhesion layer material and a metal fill material, said adhesion layer material being manganese or zinc, and said metal fill material being cobalt or copper, wherein the adhesion layer is formed by at most two steps, a first step of electroless deposit of an alloy comprising the metal fill material and the adhesion layer material, and a second step of thermal annealing of the alloy deposit causing the separation of the adhesion layer material and the metal fill material to form two separated zones: an adhesion layer and a metal fill.

Such a method comprises a step of forming openings in a dielectric layer in a substrate, wherein the openings expose a conductive surface, a step of electroless fill of the openings with an alloy comprising a first metal being cobalt or copper, and a second metal being manganese or zinc, and a step of thermal annealing of the alloy. According to this embodiment, the method comprises no step of forming an adhesion layer comprising manganese prior to the electroless fill of the openings with the alloy.

The features relating to the electrolyte and the process, and described above, may be applied, where appropriate, to the semiconductor device of the invention.

### EXAMPLE 1: ELECTRODEPOSITION OF AN ALLOY OF COBALT AND ZINC FROM A SOLUTION OF PH=2.2 ON A SUBSTRATE COMPRISING A COBALT SEED LAYER

An alloy of cobalt and zinc was electrodeposited on a flat substrate comprising a cobalt seed layer. Deposition takes place by means of a composition with a pH 2.2, containing a chloride-containing salt of cobalt(II) ions and a chloride-containing salt of zinc(II) ions in the presence of tartaric acid.

### A.—Materials and Equipment

### Substrate

The substrate used in this example consists of a 4×4 cm silicon coupon. The silicon is covered with silicon oxide in contact with a layer of tantalum 3 nm thick, which is itself covered by a cobalt layer 3 nm thick and deposited by CVD. The measured resistivity of the substrate is approximately 168 ohm/square.

### Electrodeposition Solution

The Co²⁺ concentration in this solution is 2.35 g/L, obtained from CoCl₂(H₂O)₆. The Zn²⁺ concentration is 0.136 g/L, obtained from ZnCl₂. Tartaric acid is present at 15 mg/L. The pH of the solution is adjusted to pH=2.2 by way of addition of hydrochloric acid.

### Equipment

In this example, the electrolytic deposition equipment used was composed of two parts: the cell for containing the electrodeposition solution, equipped with a fluid recirculation system so as to control the hydrodynamics of the system, and a rotating electrode equipped with a sample holder suitable for the size of the coupons used (4 cm×4 cm). The electrolytic deposition cell was composed of two electrodes:
a cobalt anode

The silicon coupon coated with the layer described above, which constitutes the cathode.

The reference is connected to the anode.

Connectors enabled the electrical contacting of the electrodes, which were connected by electrical wires to a potentiostat supplying up to 20 V or 2 A.

### B.—Experimental Protocol Preliminary Step

The substrates generally require special treatment only if the native cobalt oxide layer is too substantial, owing to wafers which are of advanced age or have been poorly stored. This storage normally takes place under nitrogen. In this case it is necessary to bring about a plasma containing hydrogen—either pure hydrogen, or a gas mixture containing 4% of hydrogen in nitrogen.

### Electrical Process

The process is performed as follows: the cathode was polarized in continuous galvanic mode in a current range from 50 mA (or 11 mA/cm²) to 120 mA (or 26 mA/cm²), for example 100 mA (or 22.1 mA/cm²). This step was carried out with rotation of 60 rpm for 1 hour. The electrolyte is contacted with the substrate before the voltage is applied, with a time of 5 seconds. The deposition rate of the alloy is 3.3 nm/s. In another embodiment, the cathode was polarized in galvano-pulsed mode in a current range from 80 mA (or 17.6 mA/cm²) to 160 mA (or 35.2 mA/cm²), for example 130 mA (or 28.6 mA/cm²), with a pulse duration of between 5 and 1000 ms in cathodic polarization, and between 5 and 1000 ms in zero polarization between two cathodic pulses.

### Annealing

Annealing is carried out at a temperature of 400° C. under a hydrogen-containing atmosphere (4% hydrogen in nitrogen) for 30 minutes, so as to bring about the migration of the zinc to the interface between SiO₂ and the cobalt.

### C.—Results Obtained

Analysis of the profiles by scanning electron microscopy shows alloy thicknesses of close to 200 nm. This thickness reduces slightly after annealing, to 190 nm. XPS analysis before annealing shows the presence of zinc in the alloy, of the order of 2 atomic %. This same form of analysis, after annealing, shows the migration of the zinc both towards the SiO₂-cobalt interface and towards the outermost surface, on the one hand. On the other hand, the total contamination with oxygen, carbon and nitrogen does not exceed 600 ppm atomic.

1. Electrolyte for electrodeposition of an alloy of a first metal selected from cobalt, copper and mixtures thereof, and a second metal selected from manganese, zinc and mixtures thereof, characterized in that the electrolyte is an aqueous solution comprising :
cobalt II ions or copper II ions in a mass concentration of from 1 g/L to 5 g/L,
chloride ions in a mass concentration of from 1 g/L to 10 g/L,
metal ions selected from manganese II ions and zinc II ions, said metal ions being in a mass concentration such that the ratio between the mass concentration of cobalt II ions or of copper II ions and the mass concentration of metal ions is from 1/10 to 25/1,
an organic acid or an inorganic acid in an amount sufficient to obtain a pH for the electrolyte being between 1.8 and 4.0, and
just one or at most two organic additives which are not polymers, wherein said organic additive, one of the two organic additives or the two organic additives may be the organic acid if present in the composition, and wherein the concentration of the organic additive or the sum of the concentrations of the two organic additives is between 5 mg/L and 200 mg/L.

2. Electrolyte according to claim 1, characterized in that the acid is a strong inorganic acid and in that the electrolyte contains a single organic additive selected from organic compounds which have a pKa of from 1.8 to 3.5.

3. Electrolyte according to claim 2, characterized in that the organic additive or at least one of the two organic additives is selected from the group consisting of citric acid, tartaric acid, malic acid, mandelic acid, maleic acid, fumaric acid, glyceric acid, orotic acid, malonic acid, L-alanine, acetylsalicylic acid and salicylic acid.

4. Electrolyte according to claim 1, characterized in that its pH is between 2.0 and 3.5.

5. Electrolyte according to claim 1, characterized in that the first metal is cobalt and the second metal is manganese.

6. Electrolyte according to claim 1, characterized in that the first metal is cobalt and the second metal is zinc.

7. Electrolyte according to claim 1, characterized in that the first metal is copper and the second metal is manganese.

8. Electrolyte according to claim 1, characterized in that the first metal is copper and the second metal is zinc.

9. Electrolyte according to claim 6, characterized in that the electrolyte is an aqueous solution comprising:
cobalt II ions in a mass concentration of from 1 g/L to 5 g/L,
chloride ions in a mass concentration of from 1 g/L to 5 g/L,
zinc II ions being in a mass concentration such that the ratio between the mass concentration of cobalt II ions and the mass concentration of zinc II ions is from 15/1 to 20/1,
an inorganic acid in an amount sufficient to obtain a pH of between 2.0 and 2.4, and
just one organic additive, the concentration of which is between 10 mg/L and 20 mg/L.

10. Electrolyte according to claim 9, characterized in that the organic additive is tartaric acid.

11. Electrochemical process for filling cavities, said cavities having an average width or an average diameter at the opening of between 15 nm and 100 nm and a depth of between 50 nm and 250 nm, said process comprising:
a step of contacting a conductive surface of said cavities with an electrolyte in accordance with one of the preceding claims,
a step of polarizing the conductive surface for a period of time sufficient to carry out the conformal and complete filling of the cavities by deposition of an alloy of a first metal selected from cobalt, copper and mixtures thereof and a second metal selected from manganese, zinc and mixtures thereof, and
a step of annealing the deposit of the alloy obtained at the end of the polarization step, said annealing being carried out at a temperature allowing the second metal to migrate to form a first layer which predominantly contains the second metal and is in contact with the conductive surface, said layer having a thickness of between 0.5 nm and 2 nm, and a second layer which contains essentially cobalt or copper and covers the surface of the first layer, the second layer not being in contact with the conductive surface.

12. Process according to claim 11, characterized in that the conductive surface is the first surface of a metallic seed layer, said metallic seed layer consisting of a third metal being different from the second metal, said metallic seed layer having a thickness of from 1 nanometre to 10 nanometres, and said metallic seed layer having a second surface that is in contact with a dielectric material comprising silicon dioxide.

13. Process according to claim 11, characterized in that the third metal is selected from the group consisting of cobalt, copper, tungsten, titanium, tantalum, ruthenium, nickel, titanium nitride, tantalum nitride, and mixtures thereof.
